(19) United States
(12) Patent Application Publication
(10) Pub. No.: US 2008/0237690 A1
(43) Pub. Date: Oct. 2, 2008

(54) SEMICONDUCTOR DEVICE AND METHOD OF MANUFACTURING THE SAME

(75) Inventors: Toru ANEZAKI, Kawasaki (JP); Kenichi OKABE, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki-shi (JP)

(21) Appl. No.: 12/055,708

(22) Filed: Mar. 26, 2008

(30) Foreign Application Priority Data
Mar. 26, 2007 (JP) 2007-080160

(51) Int. Cl. H01L 29/788; H01L 21/336

(52) U.S. Cl. 257/316; 438/264; 257/E29.3; 257/E21.422

(57) ABSTRACT

To provide a semiconductor device in which a high-performance and high-breakdown-voltage p-channel type MOS transistor having a surface channel structure and a memory cell are formed on the same substrate, and a method of manufacturing the semiconductor device. A method of manufacturing a semiconductor device including a stacked gate type nonvolatile memory cell and a p-channel type first transistor, includes: forming a gate insulating film of the first transistor on a semiconductor substrate; forming a tunnel insulating film of the stacked gate type nonvolatile memory cell on the semiconductor substrate; forming a first conductive layer containing an n-type impurity on the tunnel insulating film and the gate insulating film; and implanting p-type impurity ions to a region of the first conductive layer for forming the first transistor to turn the region of the first conductive layer into a p-type region.

### TECHNICAL FILED

This is relates to a semiconductor device including a p-channel type MOS transistor, and a method of manufacturing the same.

### BACKGROUND

Non-volatile semiconductor storage devices including a floating gate such as a flash memory accumulate charges in floating gates of transistors constituting a cell to store information and thus require as high voltage as about 12 V at the time of writing data. A high-breakdown-voltage transistor is used in a circuit for driving such a memory cell.

In the above cell driving circuit, for manufacturing reasons, a high-breakdown-voltage n-channel type MOS transistor has been mainly used.

In recent years, however, there is an increasing demand for a high-breakdown-voltage p-channel type MOS transistor as well as the high-breakdown-voltage n-channel type MOS transistor with the aim of realizing a high-performance inverter circuit or the like.

Such a p-channel type MOS transistor needs to have a deep extension region (field relaxation region) in order to ensure a high breakdown voltage.

Under the circumstances, the following technique has been proposed. That is, a gate electrode of the high-breakdown-voltage p-channel type MOS transistor is designed as a stacked gate structure so as to form a deep extension region.

According to the technique as disclosed above, a gate of a high voltage MOS transistor is formed as a stacked gate like a gate of an n-channel type MOS transistor used in a memory cell. After the formation of the stacked gate, ions are implanted to form source/drain regions.

In a semiconductor memory device as disclosed above, however, a polycrystalline silicon film 9 having the same conductivity type is formed over a memory cell region and a high voltage MOS transistor region.

Therefore, a gate electrode of a high voltage p-channel type MOS transistor has the same conductivity type as that of a transistor of the memory cell, that is, an n-type conductivity, resulting in a problem of degrading its electric characteristics.

As described above, if the gate electrode has an n-type conductivity, a high-breakdown-voltage p-channel type MOS transistor is turned into a buried channel structure from a surface channel structure, which leads to a functional decline; for example, sufficient cutoff characteristics cannot be obtained. As for MOS transistors constituting the memory cell, n-channel type transistors are used in order to implant electrons to a floating gate.

### SUMMARY

According to the embodiments, a method of manufacturing a semiconductor device including a stacked gate type nonvolatile memory cell and a p-channel type first transistor, includes: forming a gate insulating film of the first transistor over a semiconductor substrate; forming a tunnel insulating film of the stacked gate type nonvolatile memory cell over the semiconductor substrate; forming a first conductive layer containing an n-type impurity over the tunnel insulating film and the gate insulating film; implanting p-type impurity ions to a region of the first conductive layer for forming the first transistor to turn the region of the first conductive layer into a p-type region; forming an insulating layer on the first conductive layer; forming a second conductive layer over the insulating layer; patterning the second conductive layer, the insulating layer, and the first conductive layer to form a stacked gate electrode of the stacked gate type nonvolatile memory cell and a first gate electrode of the first transistor; implanting a first impurity to the semiconductor substrate using the stacked gate electrode as a mask to form a first extension region; and implanting a second impurity to the semiconductor substrate using the first gate electrode as a mask to form a second extension region.

### BRIEF DESCRIPTION OF THE DRAWINGS

FIGS. 1A and 1B are plan views showing layout of components of a NOR type flash memory, and a circuit diagram showing an equivalent circuit thereof;

FIGS. 2A and 2B are plan views showing layout of components of a NAND type flash memory, and a circuit diagram showing an equivalent circuit thereof;

FIG. 3 is a sectional view showing a schematic structure of a nonvolatile semiconductor storage device according to Example 1.

FIGS. 4A and 4B are graphs showing a correlation between an ion implant energy necessary for forming an extension region and a breakdown voltage of a transistor and a correlation between the ion implant energy and a threshold voltage Vth;

FIG. 5A shows a manufacturing process of the nonvolatile semiconductor storage device according to Example 1;

FIG. 5B shows a manufacturing process of the nonvolatile semiconductor storage device according to Example 1;

FIG. 5C shows a manufacturing process of the nonvolatile semiconductor storage device according to Example 1;

FIG. 5D shows a manufacturing process of the nonvolatile semiconductor storage device according to Example 1;

FIG. 5E shows a manufacturing process of the nonvolatile semiconductor storage device according to Example 1;

FIG. 5F shows a manufacturing process of the nonvolatile semiconductor storage device according to Example 1;

FIG. 5G shows a manufacturing process of the nonvolatile semiconductor storage device according to Example 1;

FIG. 5H shows a manufacturing process of the nonvolatile semiconductor storage device according to Example 1;

FIG. 5I shows a manufacturing process of the nonvolatile semiconductor storage device according to Example 1;

FIG. 5J shows a manufacturing process of the nonvolatile semiconductor storage device according to Example 1;

FIG. 5K shows a manufacturing process of the nonvolatile semiconductor storage device according to Example 1;

FIG. 5L shows a manufacturing process of the nonvolatile semiconductor storage device according to Example 1;

FIG. 5M shows a manufacturing process of the nonvolatile semiconductor storage device according to Example 1;

FIG. 5N shows a manufacturing process of the nonvolatile semiconductor storage device according to Example 1;

FIG. 50 shows a manufacturing process of the nonvolatile semiconductor storage device according to Example 1;

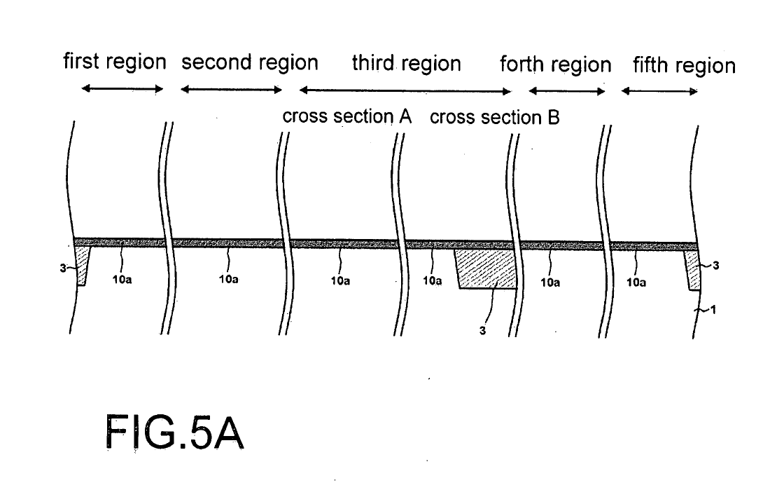

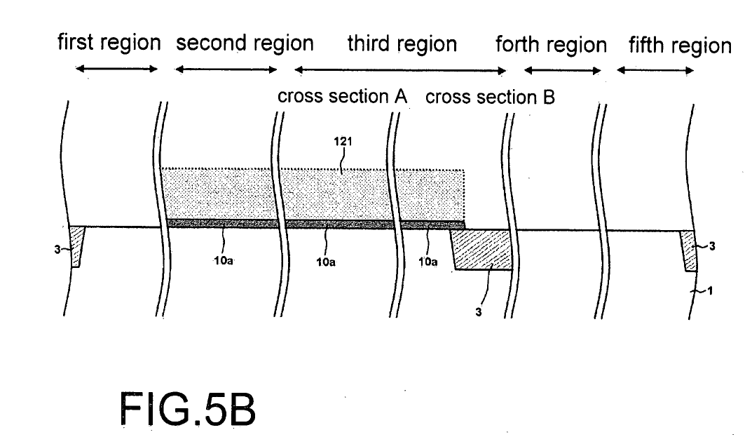

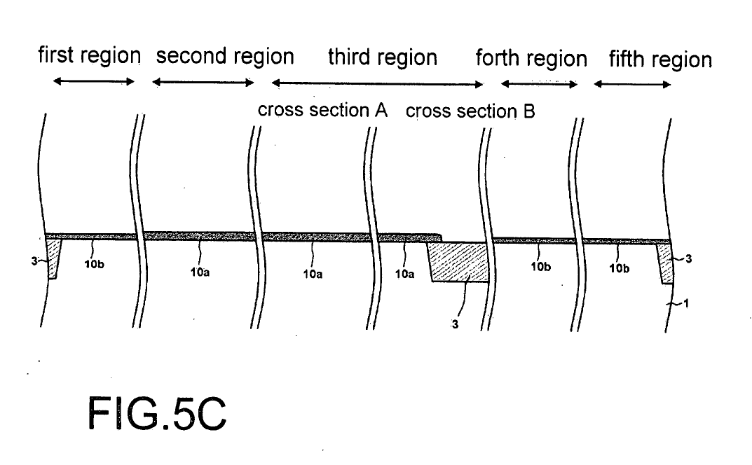

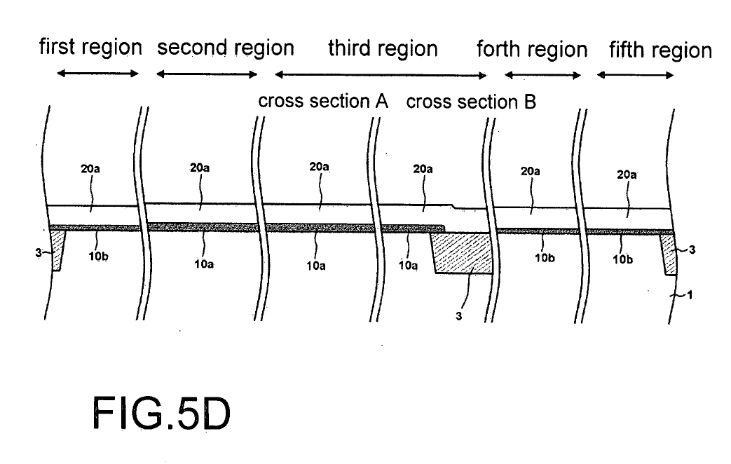

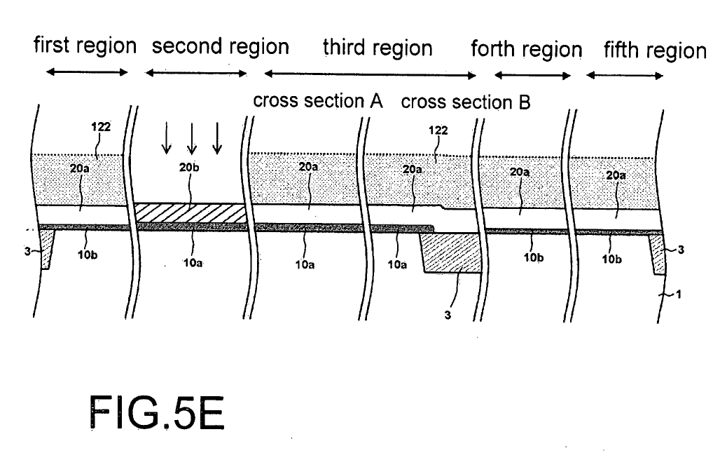

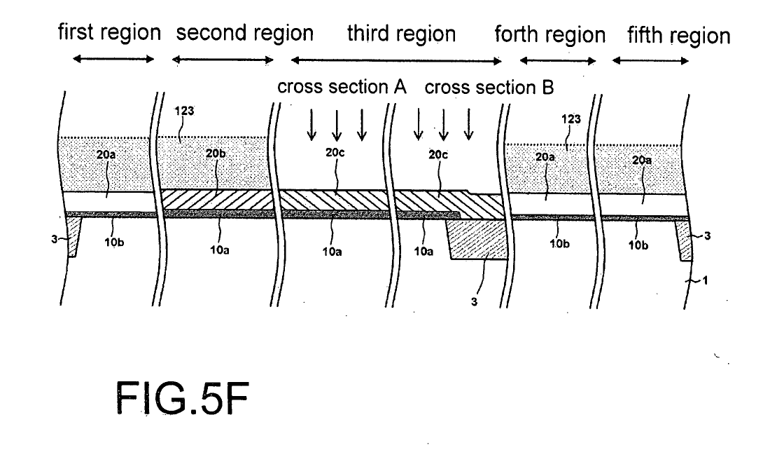

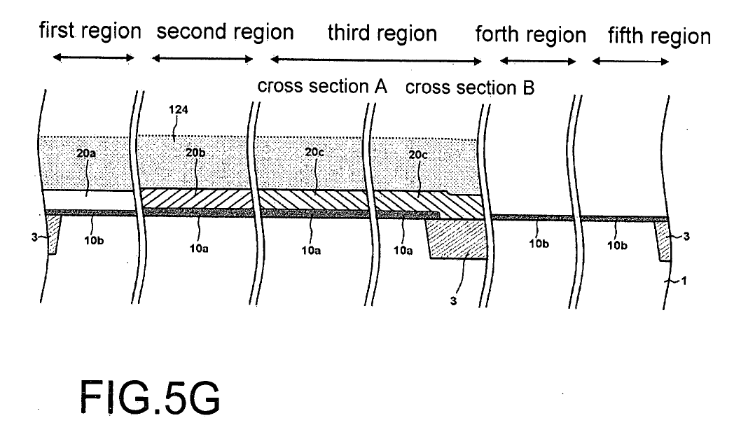

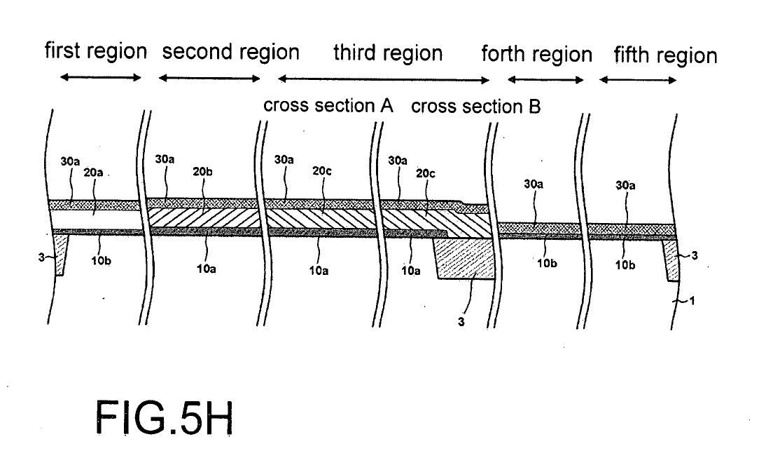

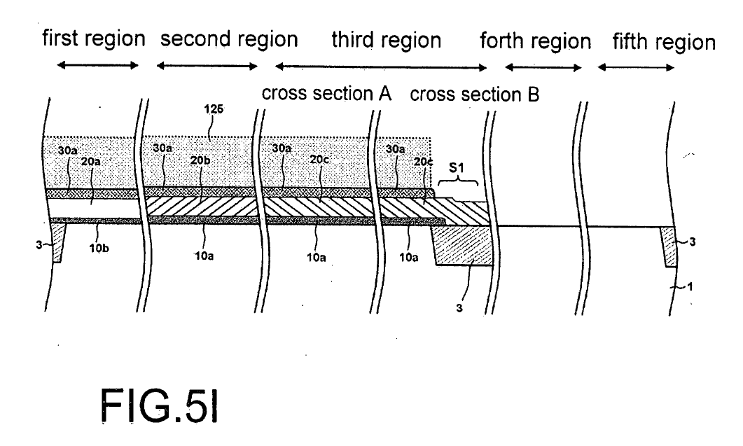

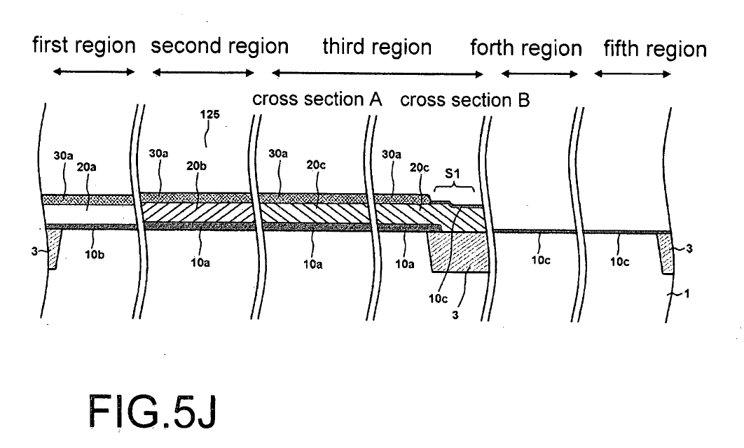

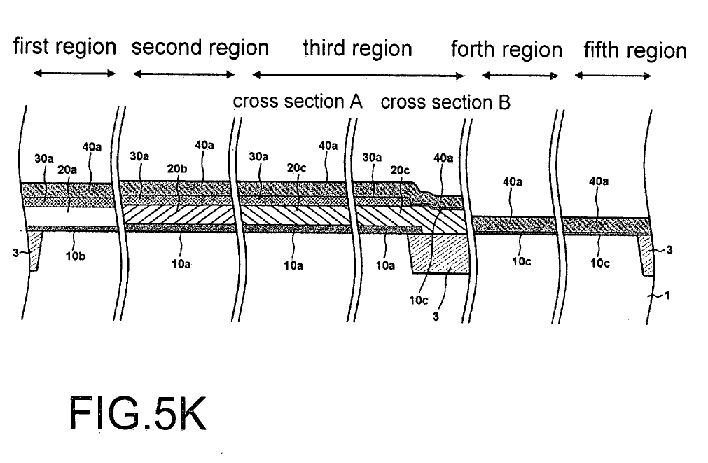

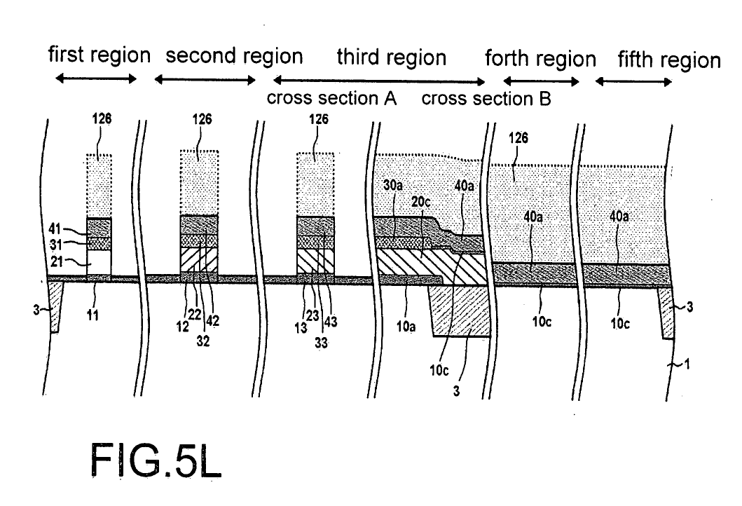

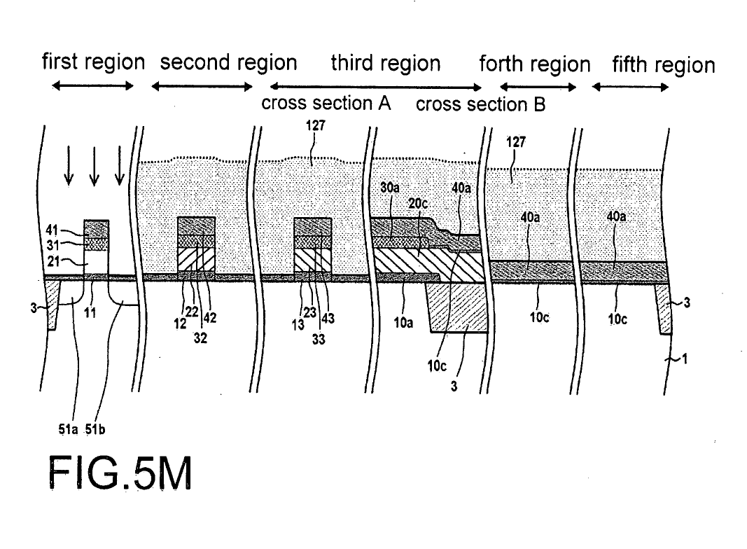

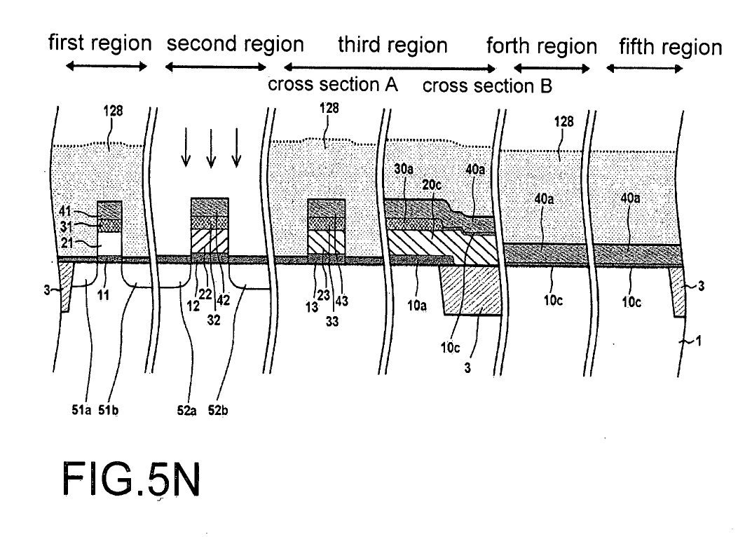

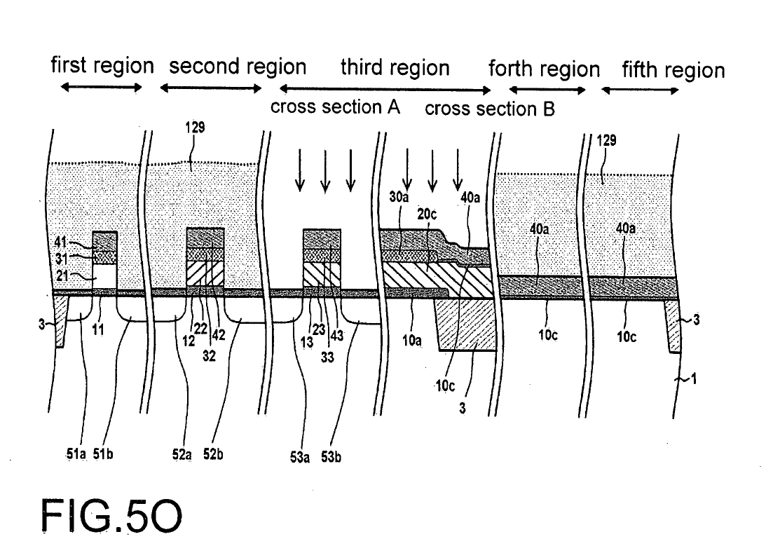

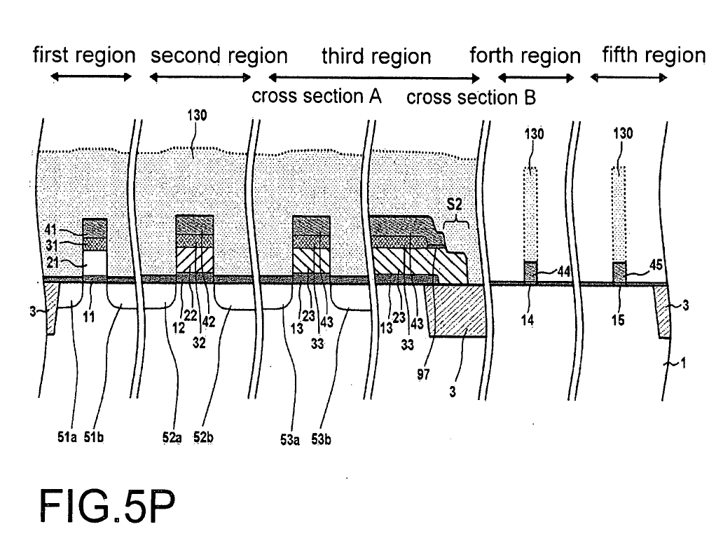

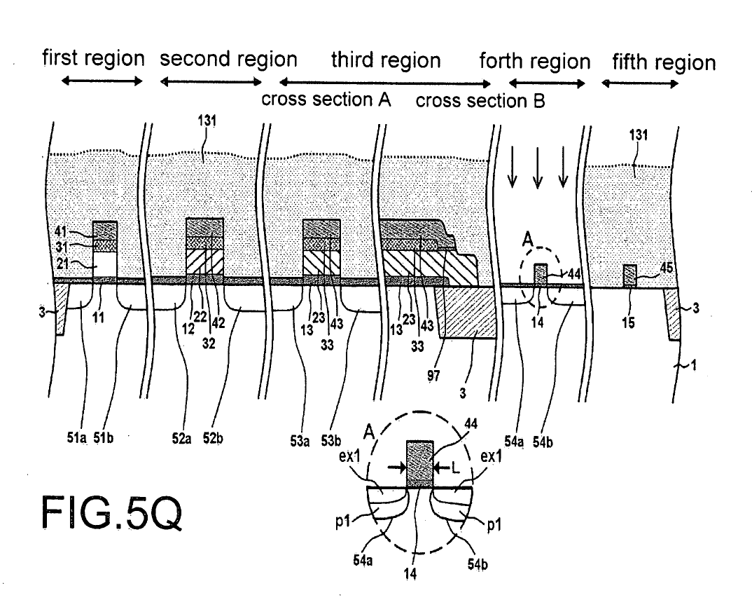

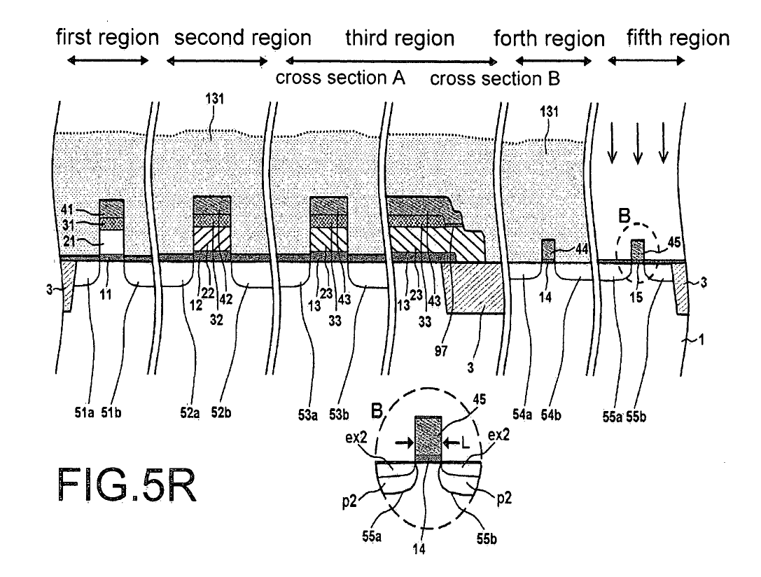

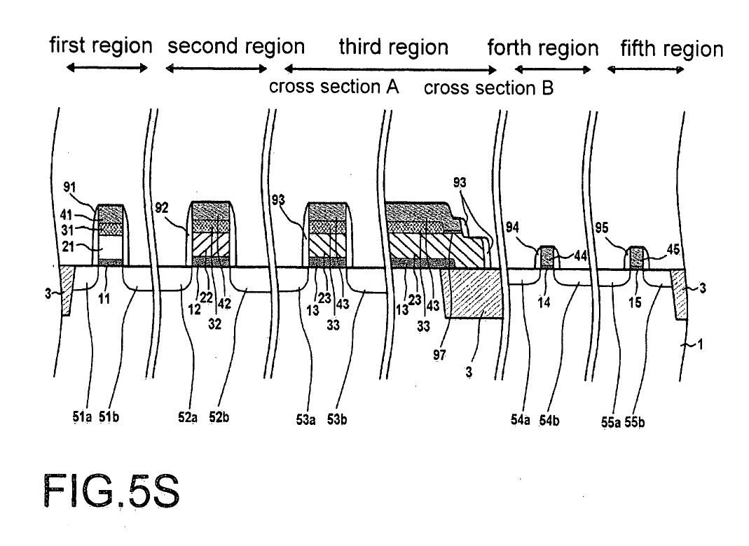

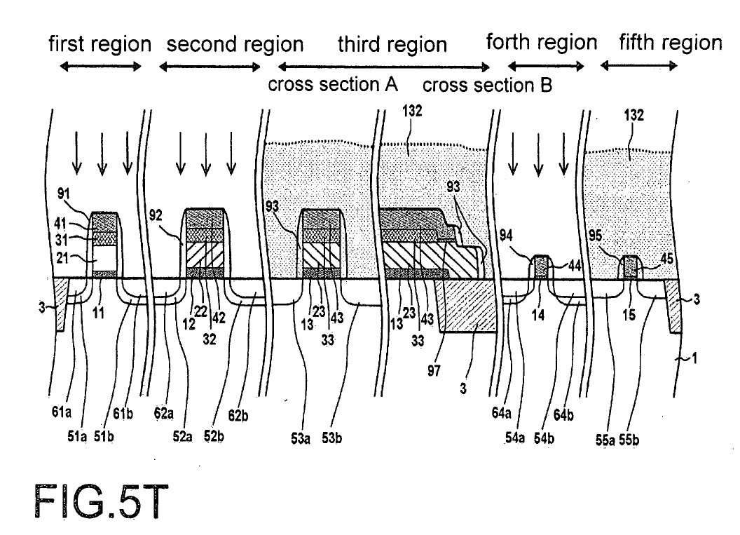

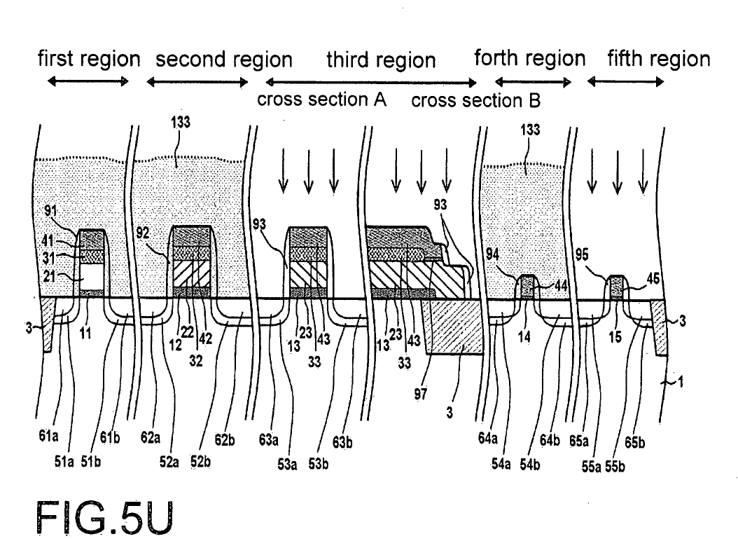

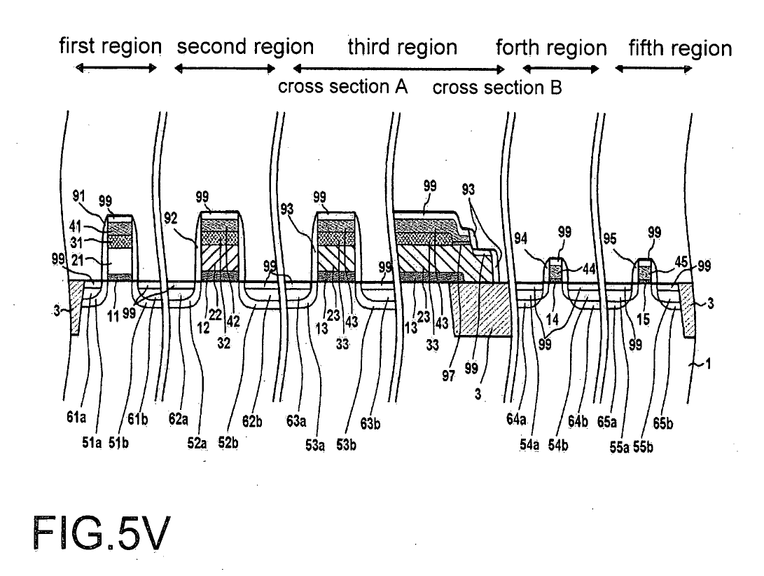

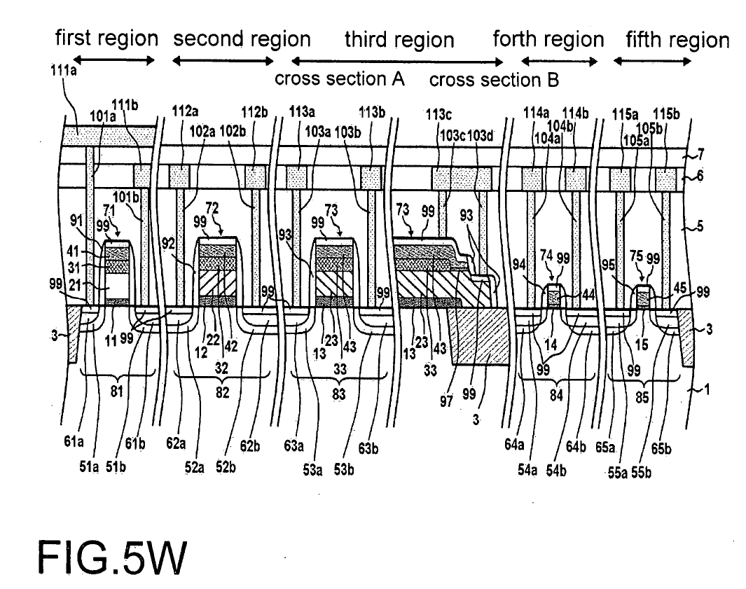

FIG. 5P shows a manufacturing process of the nonvolatile semiconductor storage device according to Example 1;

FIG. 5Q shows a manufacturing process of the nonvolatile semiconductor storage device according to Example 1;

FIG. 5R shows a manufacturing process of the nonvolatile semiconductor storage device according to Example 1;

FIG. 5S shows a manufacturing process of the nonvolatile semiconductor storage device according to Example 1;

FIG. 5T shows a manufacturing process of the nonvolatile semiconductor storage device according to Example 1;

FIG. 5U shows a manufacturing process of the nonvolatile semiconductor storage device according to Example 1;

FIG. 5V shows a manufacturing process of the nonvolatile semiconductor storage device according to Example 1; and

FIG. 5W shows a manufacturing process of the nonvolatile semiconductor storage device according to Example 1.

### DESCRIPTION OF THE PREFERRED EMBODIMENTS

Hereinafter, embodiments will be described in detail with reference to the accompanying drawings. These embodiments are given for illustrative purposes and the present invention is not limited to structures described in the following embodiments.

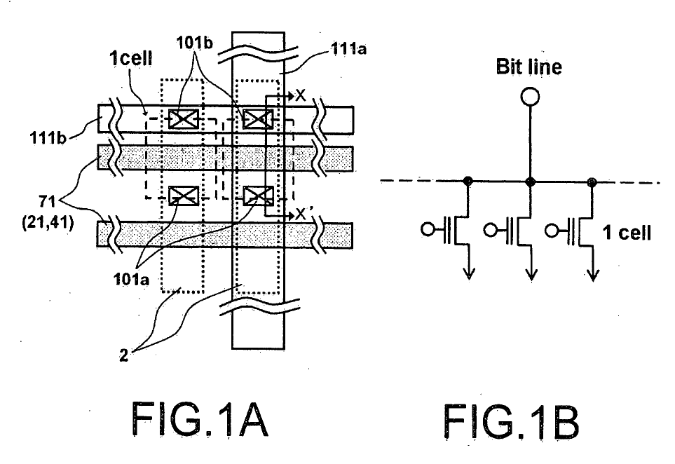

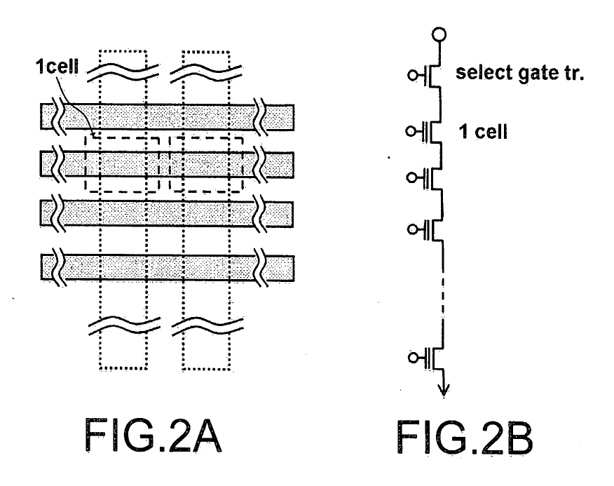

FIGS. 1A and 1B and FIGS. 2A and 2B are plan views showing layout of components of a nonvolatile semiconductor storage device according to an embodiment, and circuit diagrams showing equivalent circuits thereof. FIGS. 1A and 1B show a NOR type flash memory, and FIGS. 2A and 2B show a NAND type flash memory.

As shown in FIG. 1A, active regions 2 are formed on both sides of a gate 71 (a control gate 21 and a floating gate 41). In each active region 2, contact via holes 101a and 101b are formed. The contact via hole 101b is connected to a source line 111b extending in parallel to the gate 71, for example. The contact via hole 101a is connected to a bit line 111a extending in a direction vertical to the gate 71, for example. FIG. 1B shows an equivalent circuit of the NOR type flash memory.

In the following examples, a memory cell is described with reference to a sectional view of the NOR type flash memory taken along the line X-X′ of FIG. 1A. However, the NAND type flash memory can produce advantages similar to the NOR type flash memory.

### EXAMPLE 1

Structure of Nonvolatile Semiconductor Storage Device

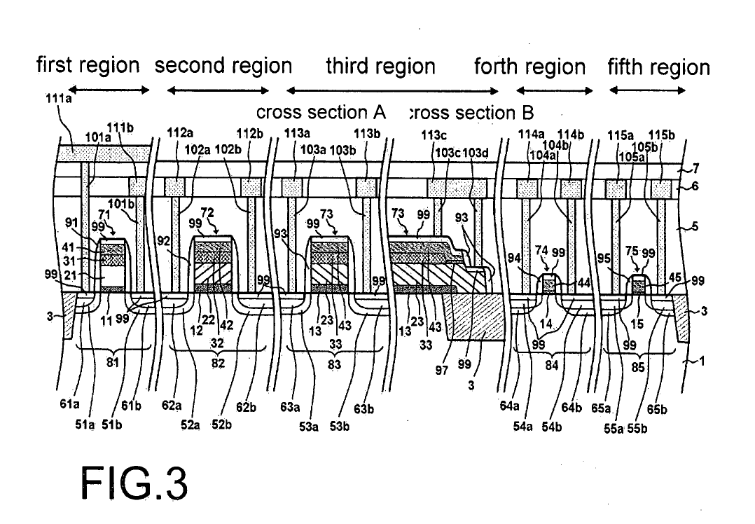

FIG. 3 is a sectional view showing a schematic structure of a nonvolatile semiconductor storage device according to Example 1. In FIG. 3, the device is divided into five circuit regions (first to fifth regions) in accordance with circuit function or performance for ease of explanation. These circuits are all formed on the same substrate. The substrate specified herein is a silicon wafer, for example. As shown in FIG. 3, a silicon substrate 5 is separated into plural element formation regions by an STI 7. The following circuits are formed in each element formation region.

First region has a memory cell with stacked gate type cell including a floating gate.

Second region has a memory cell driving circuit (circuit configured using a high-breakdown-voltage n-channel type MOS transistor)
Third region has a memory cell driving circuit configured using a high-breakdown-voltage p-channel type MOS transistor.
Fourth region has a logic circuit configured using a low-breakdown-voltage n-channel type MOS transistor.
Fifth region has a logic circuit configured using a low-breakdown-voltage p-channel type MOS transistor.

A gate electrode of a MOS transistor formed in the first region has a stacked structure where a floating gate (first electrode), an Oxide-Nitride-Oxide film (It is called “ONO film” hereafter), and a control gate (second electrode) are stacked on one another. As described in detail below, the ONO film is a laminate insulating film of an oxide film, a nitride film, and an oxide film. As a result of accumulating charges in the floating gate, a threshold voltage of the MOS transistor is changed. With such operations of the MOS transistor, information is stored in the memory cell.

First region:

The first region of FIG. 3 corresponds to the X-X′ section of FIG. 1A. As shown in FIG. 3, an n-channel type MOS transistor 81 constituting a stacked gate type memory cell is formed on a silicon substrate 1 in the first region. The n-channel type MOS transistor 81 includes a gate electrode portion 71, source/drain regions 61 including a source region 61b and a drain region 61a, and extension regions 51 including a source region side extension 51b and a drain region side extension 51a. Contact via holes 101a and 101b are formed in positions corresponding to the source/drain regions 61.

The extension regions 51 are formed in a deeper portion than the source/drain regions 61. In this way, the deep extension regions 51 are formed, so an impurity concentration is gently changed to relax an electric field. In particular, an electric field in the drain region is adjusted to thereby generate hot electrons enough to write data while keeping high-breakdown-voltage characteristics of the n-channel type MOS transistor 81. Further, the extension regions 51 are formed with a smaller thickness than gate electrodes 45 and 55 that serve as a gate electrode of a low-breakdown-voltage transistor as described below.

The contact via hole 101b has one end connected to the drain region 61b and the other end connected to the bit line 111a extending in a direction vertical to the gate electrode portion 71, for example. The contact via hole 101a has one end connected to the source region 61a and the other end connected to the source line 111b extending in parallel to the gate electrode portion 71, for example.

As shown in FIG. 3, in the gate electrode portion 71, an n-type floating gate (first electrode) 21, an ONO film 31, and an n-type control gate (second electrode) 41 are laminated in this order on a tunnel insulating film 11. In this example, the gate insulating film 11 has a thickness of, for example, about 10 nm. A floating gate 21 is formed of polycrystalline silicon lightly doped with, for example, n-type impurities. With this structure, it is possible to optimally implant electrons to the floating gate and hold the electrons. The control gate 41 is formed of, for example, polycrystalline silicon having an n-type conductivity as well. Further, side walls 91 are formed on both sides of the gate electrode portion 71. In addition, a low-resistance silicide 99 is formed on the surface of the control gate 41 and the source/drain regions 61. Prior to the formation of the side walls 91, both side walls of the gate electrode portion 71 are oxidized.

Second region:

The second region corresponds to the section of the n-channel type MOS transistor constituting the memory cell driving circuit. As shown in FIG. 3, a high-breakdown-voltage n-channel MOS transistor 82 is formed on the silicon substrate 1 in the second region. The high-breakdown-voltage n-channel MOS transistor 82 includes a gate electrode portion 72, source/drain regions 62 including a source region 62a and a drain region 62b, and extension regions 52 including a source region side extension 52a and a drain region side extension 52b. Contact via holes 102a and 102b are formed in positions corresponding to the source/drain regions 62.

The extension regions 52 are formed in a deeper portion than the source/drain regions 62. In this way, the deep extension regions 52 are formed, so an impurity concentration is gently changed to relax an electric field. As a result, the high-breakdown-voltage n-channel MOS transistor 82 achieves high breakdown voltage characteristics. The term high breakdown voltage characteristics means such breakdown voltage characteristics that a breakdown voltage is increased as an electric field is relaxed. The breakdown voltage characteristics include various characteristics of the transistor such as a source-drain voltage. Further, the extension regions 52 are formed with a smaller thickness than the gate electrodes 45 and 55 that serve as a gate electrode of a low-breakdown-voltage transistor as described below.

The contact via hole 102a has one end connected to the source region 62a and the other end connected to a line 112a extending in parallel to the gate electrode portion 72, for example. The contact via hole 102b has one end connected to the drain region 62b and the other end connected to a line 112b extending in a direction vertical to the gate electrode portion 72, for example.

As shown in FIG. 3, in the gate electrode portion 72, an electrode 22, an ONO film 32, and an electrode 42 are laminated in this order on a gate insulating film 12. In this example, the gate insulating film 12 has a thickness of, for example, about 15 nm. The electrode 22 is formed together with the floating gate 21. The electrode 42 is formed together with the control gate 41. The electrodes 22 and 42 are formed of polycrystalline silicon (polysilicon) doped with, for example, n-type impurities. Further, side walls 92 are formed on both sides of the gate electrode portion. In addition, the low-resistance silicide 99 is formed on the surface of the control gate 42 and the source/drain regions 62. Prior to the formation of the side walls 92, both side walls of the gate electrode portion 72 are oxidized.

Third region:

The third region corresponds to the section of the p-channel type MOS transistor constituting the memory cell driving circuit. As shown in FIG. 3, a high-breakdown-voltage p-channel MOS transistor 83 is formed on the silicon substrate 1 in the third region. The high-breakdown-voltage p-channel MOS transistor 83 includes a gate electrode portion 73, source/drain regions 63 including a source region 63a and a drain region 63b, and extension regions 53 including a source region side extension region 53a and a drain region side extension region 53b. Contact via holes 103a and 103b are formed in positions corresponding to the source/drain regions 63.

The extension regions 53 are formed in a deeper portion than the source/drain regions 63. In this way, the deep extension regions 53 are formed, so an impurity concentration is gently changed to relax an electric field. As a result, the high-breakdown-voltage p-channel MOS transistor 83 achieves high breakdown voltage characteristics. The term high breakdown voltage characteristics means such breakdown voltage characteristics that a breakdown voltage is increased as an electric field is relaxed. The breakdown voltage characteristics include various characteristics of the transistor such as a source-drain voltage. Further, the extension regions 53 are formed with a smaller thickness than the gate electrodes 45 and 55 that serve as a gate electrode of a low-breakdown-voltage transistor as described below.

The contact via hole 103a has one end connected to the source region 63a and the other end connected to a line 113a extending in parallel to the gate electrode portion 73, for example. The contact via hole 103b has one end connected to the drain region 63b and the other end connected to a line 113b extending in a direction vertical to the gate electrode portion 73, for example.

As shown in FIG. 3, in the gate electrode portion 73, an electrode 23, an ONO film 33, and an electrode 43 are laminated in this order on a gate insulating film 13. In this example, the gate insulating film 13 has a thickness of, for example, about 15 nm. The electrode 23 is formed together with a floating gate 23. The electrode 43 is formed together with a control gate 43. The electrodes 23 and 43 are formed of polycrystalline silicon doped with, for example, p-type impurities. The electrode 23 contains n-type impurities as well as the p-type impurities. Since a concentration of the p-type impurities is higher than that of the n-type impurities, the electrode 23 exhibits a p-type conductivity. Further, side walls 93 are formed on both sides of the gate electrode portion. In addition, the low-resistance silicide 99 is formed on the surface of the control gate 43 and the source/drain regions 63. Prior to the formation of the side walls 93, both side walls of the gate electrode portion 73 are oxidized.

Further, the third region corresponds to a section taken along the line parallel to a longitudinal direction of the gate electrode portion 73 as well as the section (section A) taken along the line vertical to the longitudinal direction of the gate electrode portion 73. The section vertical to the section A is defined as “section B”. The section B is a section of an end portion of the gate electrode portion of the section A.

As illustrated in the section B, the electrodes 23 and 43 are electrically connected together at the end of the gate electrode portion 73 through contact via holes 103c and 103d. This is because a silicon oxynitride film 97 is formed on the electrode 43 at the end of the gate electrode portion 73 during a manufacturing process, and the electrodes 23 and 43 are not electrically connected together. To be specific, one end of the contact via hole 103c is connected to the electrode 43, and the other end thereof is connected to a line 113c formed in an interlayer insulating film 6. Further, one end of the contact via hole 103d is connected to the electrode 23, and the other end thereof is connected to the line 113c similar to the other end of the contact via hole 103c. The second region is desirably structured like the section B. That is, the electrodes 22 and 42 are electrically connected.

Fourth region:

The fourth region corresponds to the section of the n-channel type MOS transistor constituting the logic circuit. As shown in FIG. 3, a low-breakdown-voltage n-channel MOS transistor 84 is formed on the silicon substrate 1 in the fourth region. The low-breakdown-voltage n-channel MOS transistor 84 includes a gate electrode portion 74, source/drain regions 64 including a source region 64a and a drain region 64b, and extension pocket regions 54 including a source region side extension pocket region 54a and a drain region side extension pocket region 54b. Contact via holes 104a and 104b are formed in positions corresponding to the source/drain regions 64. The extension pocket regions 54 of the low-breakdown-voltage n-channel MOS transistor 84 are formed in a shallower portion than the source/drain regions 64.

The contact via hole 104a has one end connected to the source region 64a and the other end connected to a line 114a extending in parallel to the gate electrode portion 74, for example. The contact via hole 104b has one end connected to the drain region 64b and the other end connected to a line 114b extending in a direction vertical to the gate electrode portion 74, for example.

As shown in FIG. 3, in the gate electrode portion 74, a gate electrode 44 is laminated on a gate insulating film 14. In this example, the gate insulating film 14 has a thickness of, for example, about 3 nm. The electrode 44 is formed together with the control gate 41, for example. The electrode 44 is formed of polycrystalline silicon doped with, for example, n-type impurities. Further, side walls 94 are formed on both sides of the gate electrode portion. In addition, the low-resistance silicide 99 is formed on the surface of the gate electrode 44 and the source/drain regions 64.

Fifth region:

The fifth region corresponds to the section of the p-channel type MOS transistor constituting the logic circuit. As shown in FIG. 3, a low-breakdown-voltage p-channel MOS transistor 85 is formed on the silicon substrate 1 in the fifth region. The low-breakdown-voltage p-channel MOS transistor 85 includes a gate electrode portion 75, source/drain regions 65 including a source region 65a and a drain region 65b, and extension pocket regions 55 including a source region side extension pocket region 55a and a drain region side extension pocket region 55b. Contact via holes 105a and 105b are formed in positions corresponding to the source/drain regions 65. The extension pocket regions 55 of the low-breakdown-voltage p-channel MOS transistor 85 are formed in a shallower portion than the source/drain regions 65.

The contact via hole 105a has one end connected to the source region 65a and the other end connected to a line 115a extending in parallel to the gate electrode portion 75, for example. The contact via hole 105b has one end connected to the drain region 65b and the other end connected to a line 115b extending in a direction vertical to the gate electrode portion 75, for example.

As shown in FIG. 3, in the gate electrode portion 75, a conductive film 45 is laminated on a gate insulating film 15. The conductive film 45 is formed together with the control gate 41, for example. The conductive film 45 is formed of polycrystalline silicon doped with, for example, p-type impurities. Further, side walls 95 are formed on both sides of the gate electrode portion. In addition, the low-resistance silicide 99 is formed on the surface of the gate electrode 45.

As described above, in this example, the high-breakdown-voltage MOS transistor, the low-breakdown-voltage MOS transistor, and the memory cell are formed on the same substrate. That is, the high-breakdown-voltage n-channel type MOS transistor 82 and p-channel type MOS transistor 83, the low-breakdown-voltage n-channel type MOS transistor 84 and p-channel type MOS transistor 85, and the memory cell are formed on the same substrate. As described in detail below, a gate electrode of the low-breakdown-voltage transistor is formed in a conductive layer for forming a control gate of the high-breakdown-voltage transistor from the viewpoint of manufacturing a device with a simple process.

To give a specific example thereof, high-speed logic circuits using a low-breakdown-voltage transistor are mounted around a memory cell. In such an example, a high-breakdown-voltage transistor is driven at a voltage of about 12 V, but the low-breakdown-voltage transistor is driven at a voltage lower than 1.8 V, for example.

To ensure a high breakdown voltage, it is necessary to suppress a current that flows from a drain region to a substrate due to band-to-band phenomenon, gated junction leak, or other such factors. To suppress this current, it is effective to relax an electric field at the junction. Ions should be implanted at high acceleration energy to form deep extension regions. To that end, it is necessary to form a gate electrode used as a mask for ion implantation with a large thickness to prevent doped impurities from reaching a channel region.

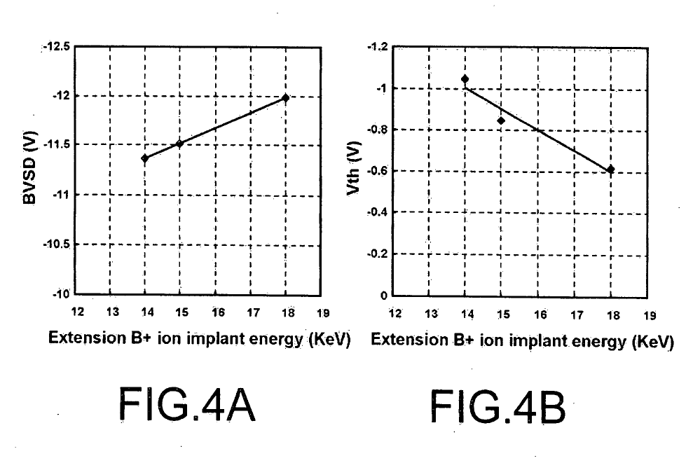

If impurity ions reach the channel region through the gate electrode, various problems occur. FIGS. 4A and 4B are graphs showing a correlation between an ion implant energy necessary for forming an extension region and a breakdown voltage of a transistor and a correlation between the ion implant energy and a threshold voltage Vth, under the condition that a p-channel type MOS transistor is used with a gate electrode length L of 10 μm, a source-drain width W of 10 μm, and a gate electrode thickness of 100 nm. The gate electrode length L is a length between the source region and the drain region, that is, a width of the gate electrode. As shown in FIG. 4A, if boron ions (B+) are applied at an acceleration energy of 18 KeV, a breakdown voltage of 12 V can be ensured. However, at this time, as shown in FIG. 4B, the threshold voltage Vth drops down to 0.6 V. This phenomenon occurs due to boron ions (B+) that reach the channel region through the gate electrode. The phenomenon that the ions pass through the gate electrode is undesirable because characteristics of transistors might vary. There is another problem that a reliability of the gate electrode itself declines.

On the other hand, in recent years, a width of a gate electrode of a high-speed logic circuit has been scaled down to about 40 to 90 nm. In general, if a gate electrode height is about twice larger than a width, pattern collapse occurs. Therefore, it is necessary to decrease the gate height in accordance with the gate width not to cause the pattern collapse.

The above structure of this example can satisfy both of the above two demands. That is, this structure enables formation of a high-breakdown-voltage p-channel type MOS transistor having a surface channel structure, a low-breakdown-voltage transistor, and a memory cell on the same substrate, and fine patterning of a gate electrode of the low-breakdown-voltage transistor.

Manufacturing Process of Semiconductor Device

An actual manufacturing process of the nonvolatile semiconductor storage device of FIG. 3 is described next. FIGS. 5 to 26 show main steps of a manufacturing process of the nonvolatile semiconductor storage device of Example 1.

Step 1

In this step, an shallow trench isolation (STI) 3 is formed on the substrate 1 to separate the substrate 1 into plural element formation regions as shown in FIG. 5A. As the substrate 1, for example, a P-type silicon wafer lightly doped with a p-type impurity element such as boron (B) is used. Next, a well region (not shown) is formed in the silicon substrate 1 having the STI 3 formed thereon. Mower specifically, a p-type well region is formed in the first, second, and fourth regions for forming an n-channel type MOS transistor, and an n-type well region is formed in the third and fifth regions for forming a p-channel type MOS transistor. Further, ions are optimally implanted to a surface portion of the substrate 1 in the first to third regions, for example, to adjust the threshold voltage Vth of the MOS transistor.

Next, a silicon oxide film (SiO₂ film) 10a for forming a gate insulating film is formed over the entire surface of the substrate 1. The silicon oxide film 10a is formed into a thickness of about 15 nm through wet oxidization, for example.

Step 2

In this step, as shown in FIG. 5B, the silicon oxide film 10a is partially removed. To be specific, a resist 121 is formed to cover regions for forming a high-breakdown-voltage transistor (second and third regions). After that, the silicon oxide film 10a not covered with the resist 121 (first, fourth, and fifth regions) is etched off with a hydrofluoric acid (HF) aqueous solution, for example. As a result, the surface of the substrate 1 is exposed in the first, fourth, and fifth regions.

Step 3

In this step, as shown in FIG. 5C, a silicon oxynitride (SiON) film 10b is formed as a gate insulating film in the first, fourth, and fifth regions. To be specific, the silicon oxynitride film 10b is formed into a thickness of, for example, about 10 nm through thermal nitriding/oxidizing treatment.

Step 4

In this step, as shown in FIG. 5D, an n-type conductive layer (first conductive layer) 20a is formed on the substrate 1. More specifically, phosphorous (P)-doped amorphous silicon is deposited on the substrate 1 having the silicon oxide film 10a and the silicon oxynitride film 10b formed thereon by low pressure-chemical vapor deposition (LP-CVD) to thereby form the conductive layer 20a. The conductive layer 20a has a thickness of, for example, 90 nm. Here, amorphous silicon not doped with P may be deposited. In this case, the conductive layer 20a in the first region needs to be doped with n-type impurities. At this time, it is desirable to dope the n-type impurities to the conductive layer 20a with a dosage of, for example, 1×10²⁰/cm³.

Step 5

In this step, as shown in FIG. 5E, phosphorous (P) or arsenic (As) is doped to the first conductive layer 20a in the second region. To be specific, a resist 122 is formed on the entire surface of the layer except the surface in the second region. After that, the conductive layer 20a is doped with P or As. At this time, the impurities are doped through ion implantation. As a result, an n-type conductive layer 20b having a high impurity concentration is formed in the second region. If the conductive layer 20a is formed with a high concentration of n-type impurities, this process may be skipped.

Step 6

In this step, as shown in FIG. 5F, boron (B) or boron fluoride (BF₂) is doped to the first conductive layer 20a in the third region. To be specific, a resist 123 is formed on the entire surface of the layer except the third region. After that, the conductive layer 20a is doped with boron (B) or boron fluoride (BF₂) (for example, through ion implantation). At this time, B+ ions are implanted at an acceleration energy of 5 KeV with a dosage of 1×10¹⁵/cm², for example. Then, p-type impurities are doped to the first conductive layer 20a with a high dosage compared to a concentration of n-type impurities contained in the first conductive layer 20a. As a result, a first conductive layer 20c highly doped with p-type impurities is formed. That is, as a result of doping, the conductive layer 20c contains not only n-type impurities but p-type impurities with a higher concentration than that of the n-type impurities. Such doping is also called counter doping.

Step 7

In this step, as shown in FIG. 5G, the first conductive layer 20a in the fourth and fifth regions is removed. More specifically, a resist 124 is formed to cover regions for forming the memory cell and the high-breakdown-voltage transistor (first to third regions). After that, the conductive layer 20a in the fourth and fifth regions is removed through dry etching with a hydrobromic acid (HBr) gas. The removal of the conductive layer 20a may be performed before doping in steps 5 and 6.

Step 8

In this step, as shown in FIG. 5H, an ONO film 30a is formed over the entire surface of the substrate 1. To be specific, an SiO₂ film having a thickness of 5 to 10 nm and an SiN film having a thickness of 5 to 10 nm are formed on the substrate 1 by CVD, for example. After that, an SiO₂ film having a thickness of 3 to 10 nm is formed on the surface of the SiN film through thermal oxidation, for example. The ONO film functions to prevent charges in the floating gate from leaking to the control gate. In this case, the first conductive layers 20a, 20b, and 20c are crystallized and turned into polycrystalline silicon due to heat applied upon forming the ONO film.

Although not shows, ions are implanted to the layer in the fourth and fifth regions through the ONO film 30a and the silicon oxynitride film 10b so as to adjust the threshold voltage Vth of the transistor.

Step 9

In this step, as shown in FIGS. 13 and 14, after the partial removal of the ONO film 30a and the silicon oxynitride film 10b, an SiON film 10c is formed as a gate insulating film on the substrate 1 in the fourth and fifth regions. To be specific, a resist 125 is formed to cover the first, second, and the third regions. In the third region, as shown in FIG. 5I, the resist 125 is formed not to cover a contact region S1 for connecting the gate electrodes 23 and 43. Next, the ONO film 30a and the SiON film 10c in the contact region S1 and the fourth and fifth regions are removed using dry etching with a hydrobromic acid (HBr) gas and wet etching with a hydrofluoric acid (HF) aqueous solution in combination, for example.

Next, as shown in FIG. 5J, the resist 125 is removed, after which a silicon oxynitride film 10c is formed into a thickness of, for example, about 2 nm through thermal nitriding/oxidizing treatment. The silicon oxynitride film 10c is also formed in the contact region S1 in the third region as well as the fourth and fifth regions.

Step 10

In this step, as shown in FIG. 5K, a conductive layer (second conductive layer) 40a is formed over the entire surface of the substrate 1. To elaborate, polycrystalline silicon is deposited into a thickness of about 100 nm by LP-CVD, for example, to cover the ONO film 30a formed on the substrate 1. The conductive layer 40a is not doped with any impurity.

Step 11

In this step, as shown in FIG. 5L, predetermined portions of the memory cell and the high-breakdown-voltage transistor, which are used to form a gate, are patterned. More specifically, a resist 126 is formed not to cover each gate portion of transistors formed in these regions. The resist 126 is formed over the entire surface thereof in the fourth and fifth regions. Next, the conductive layer 40a, the ONO film 30a, and the conductive layers 20a, 20b, and 20c are etched in order. As a result, each gate electrode portion of the transistors formed in the first to third regions is formed. The gate electrode portion has a stacked structure having the thickness of about 200 nm.

Step 12

In this step, as shown in FIG. 5M, the extension regions 51 are formed in an n-channel type MOS transistor 81 constituting the memory cell. More specifically, as shown in FIG. 5M, a resist 127 is first formed on the substrate except the first region. Next, phosphorous (P+) ions or arsenic (As+) ions are implanted at an acceleration voltage of 30 to 80 KeV with a dosage of 1×10¹⁴/cm³, for example. In this way, ion implantation is performed using the gate electrode having a stacked structure as a mask. As a result, the extension regions 51 of the n-channel type MOS transistor 81 are formed in a self-alignment manner with respect to the gate electrode. The gate electrode of a stacked structure has a thickness of about 200 nm, so P+ or As+ ions never reach the substrate 1 surface through the gate electrode portion.

Step 13

In this step, as shown in FIG. 5N, extension regions 52 are formed in a high-breakdown-voltage n-channel type MOS transistor 82. More specifically, as shown in FIG. 5N, a resist is first formed on the substrate except the second region. Next, phosphorous (P+) ions or arsenic (As+) ions are implanted at an acceleration voltage of 40 to 80 KeV with a dosage of 1×10¹³ to 5×10¹⁴/cm³, for example. In this way, ion implantation is performed using the gate electrode having a stacked structure as a mask. As a result, the extension regions 52 of the n-channel type MOS transistor 82 are formed in a self-alignment manner with respect to the gate electrode. The gate electrode of a stacked structure has a thickness of about 200 nm, so P+ or As+ ions never reach the substrate 1 surface through the gate electrode portion.

Step 14

In this step, as shown in FIG. 5O, extension regions 53 are formed in a high-breakdown-voltage p-channel type MOS transistor 83. More specifically, as shown in FIG. 5O, a resist is first formed on the substrate except the third region. Next, boron (B+) ions or boron fluoride (BF₂+) ions are implanted at an acceleration voltage of 18 to 25 KeV with a dosage of 1×10¹³ to 1×10¹⁴/cm², for example. In this way, ion implantation is performed using the gate electrode having a stacked structure as a mask. As a result, the extension regions 53 of the p-channel type MOS transistor 83 are formed in a self-alignment manner with respect to the gate electrode. The gate electrode of a stacked structure has a thickness of about 200 nm, so B+ or BF₂+ ions never reach the substrate 1 surface through the gate electrode portion.

Step 15

In this step, as shown in FIG. 5P, dry oxidation is performed at high temperatures and then, a gate of a low-breakdown-voltage transistor is formed. To be specific, after the removal of a resist 129, the substrate in the third region is subjected to dry oxidation at about 950° C., for example to oxidize side walls of the gate electrode. At this time, the gate electrode is oxidized by about 10 nm, for example. This oxidation process is carried out after the extension region formation to thereby realize a gentle concentration profile of the extension region. That is, an impurity concentration is gently changed to relax an electric field. As a result, the p-channel type MOS transistor 83 obtains higher breakdown voltage characteristics.

Next, as shown in FIG. 5P, the conductive layer 40a in a region S2 of the contact region S1 in the third region is removed. In addition, in this process, a gate electrode portion of the low-breakdown-voltage transistor is patterned. More specifically, a resist 130 is formed on the substrate except a gate electrode portion of each transistor formed in the fourth and fifth region. The resist 130 is formed over the entire surface of the substrate in the first to third regions. Next, the conductive layer 40a is etched. As a result, gates 44 and 45 of the low-breakdown-voltage n-channel type MOS transistor 84 formed in the fourth region and the low-breakdown-voltage p-channel type MOS transistor 85 formed in the fifth region are formed. The gate electrodes 44 and 45 have a thickness of about 100 nm.

Step 16

In this step, as shown in FIG. 5Q, the extension pocket regions 54 are formed in a low-breakdown-voltage n-channel type MOS transistor 84. The extension pocket regions 54 include an extension region ex1 and a pocket region p1 as shown in an enlarged view A of FIG. 5Q. More specifically, as shown in FIG. 5Q, a resist 130 is first formed on the substrate except the fourth region. Next, arsenic (As+) ions are implanted at an acceleration voltage of 2 to 4 KeV with a dosage of 5×10¹⁴ to 3×10¹⁵/cm², for example to form the extension region. Next, indium (In+) ions are implanted at an acceleration voltage of 30 to 50 KeV with a dosage of 1×10¹⁴ to 1×10¹⁵/cm², for example to form the pocket region. In this way, ion implantation is performed using the gate electrode having a single-layer structure as a mask. As a result, the extension pocket regions 54 of the n-channel type MOS transistor 84 are formed in a self-alignment manner with respect to the gate electrode. The gate electrode portion has a thickness of about 100 nm. Since the gate electrode is thin, the extension region ex1 is formed in a shallower portion than the extension regions 52 and 53 for the high-breakdown-voltage MOS transistor in order to prevent punch-through of impurities. Further, since the gate electrode is thin, pattern collapse is prevented. As a result, the n-channel type MOS transistor 84 having a smaller gate electrode length L can be formed.

Step 17

In this step, as shown in FIG. 5R, the extension pocket regions 55 are formed in a low-breakdown-voltage p-channel type MOS transistor 85. The extension pocket regions 55 include an extension region ex2 and a pocket region p2 as shown in an enlarged view B of FIG. 5R. More specifically, as shown in FIG. 5R, a resist 131 is first formed on the substrate except the fifth region. Next, boron (B+) ions are implanted at an acceleration voltage of 0.1 to 0.5 KeV with a dosage of 5×10¹⁴ to 3×10¹⁵/cm², for example to form the extension region. Next, arsenic (As+) ions are implanted at an acceleration voltage of 30 to 60 KeV with a dosage of 1×10¹⁴ to 1×10¹⁵/cm², for example to form the pocket region. In this way, ion implantation is performed using the gate electrode having a single-layer structure as a mask. As a result, the extension pocket regions 55 of the p-channel type MOS transistor 85 are formed in a self-alignment manner with respect to the gate electrode. The gate electrode portion has a thickness of about 100 nm. Since the gate electrode is thin, the extension region ex2 is formed in a shallower portion than the extension regions 52 and 53 for the high-breakdown-voltage MOS transistor in order to prevent punch-through of impurities. Further, since the gate electrode is thin, pattern collapse is prevented. As a result, the p-channel type MOS transistor 85 having a smaller gate electrode length L can be formed.

Step 18

In this step, as shown in FIG. 5S, side walls are formed in the gate portion of the transistor. More specifically, a silicon nitride (SiN) film (not shown) having a thickness of about 100 nm is formed by LP-CVD, for example. Next, the SiN film is subjected to anisotropic etching to thereby form side walls on both sides of the gate portion of the transistor formed in the previous step.

Step 19

In this step, as shown in FIG. 5T, source/drain regions 61, 62, and 64 of the n-channel type MOS transistor are formed. More specifically, a resist 132 is formed in the third and fifth regions. Next, phosphorous (P+) ions or arsenic (As+) ions are implanted at an acceleration voltage of 5 KeV with a dosage of 5×10¹⁵/cm², for example. At this time, phosphorous (P+) ions or arsenic (As+) ions are also implanted to an upper portion of each gate of the n-channel type transistor, that is, the electrodes 41 and 42 and the gate electrode 44, which are formed using the conductive layer 40a.

Step 20

In this step, as shown in FIG. 5U, source/drain regions 63 and 65 of the p-channel type MOS transistor are formed. More specifically, a resist 133 is formed in the first, second, and fourth regions. Next, boron (B+) ions or boron fluoride (BF₂+) ions are implanted at an acceleration voltage of 5 KeV with a dosage of 5×10¹⁵/cm², for example. At this time, boron (B+) ions or boron fluoride (BF₂+) ions are also implanted to an upper portion of each gate of the p-channel type transistor, that is, the electrode 43 and the gate electrode 45, which are formed using the conductive layer 40a.

Step 21

In this step, as shown in FIG. 5V, the source/drain regions are turned into silicide regions. More specifically, a cobalt (Co) film (not shown) is first formed into a thickness of about 30 nm on the substrate 1 by sputtering or the like. Next, the Co film is annealed at about 500° C. for 30 seconds. Next, a mixed solution of HN₂OH, H₂0₂, and H₂0 is applied thereto for about 10 minutes to remove the Co film that has not been turned into silicide. As a result, as shown in FIG. 5V, the source/drain regions 61 to 65 and the electrodes 41 to 43 and the gate electrodes 44 and 45 as the upper portion of each gate made of polycrystalline silicon are turned into silicide.

Step 22

In this step, as shown in FIG. 5W, an interlayer insulating film and lines are formed on the substrate 1 having the transistors 81 to 85 formed thereon. To be specific, an interlayer insulating film 5, contact via holes 101b, 102a, 102b, 103a, 103b, 103c, 103d, 104a, 104b, 105a, and 105b are formed. Next, an interlayer insulating film 6 and contact via holes 111b, 112a, 112b, 113a, 113b, 113c, 114a, 114b, 115a, and 115b are formed. Next, an interlayer insulating film 7, a line 101a, and a bit line 111a are formed. Here, the electrode 23 is connected to the upper line 113c, for example, at the end of the gate electrode portion 73 to thereby electrically connect the electrode 23 with the other circuit in a small area. Further, the electrodes 23 and 43 are electrically connected through the contact via holes 103c and 103d. If the electrodes 23 and 43 are electrically connected in this way, a local line can directly connect the gate electrode portion 73 and the other gate electrode portion, for example.

With the above structure, according to this example, the high-breakdown-voltage p-channel type MOS transistor having the surface channel structure and the memory cell can be formed on the same substrate. In addition, in the case where the high-breakdown-voltage p-channel type MOS transistor, the low-breakdown-voltage MOS transistor, and the memory cell are formed on the same substrate, a nonvolatile semiconductor storage device including these transistors can be manufactured with a simple process while preventing pattern collapse of the gate of the low-breakdown-voltage MOS transistor. That is, it is possible to manufacture a nonvolatile semiconductor storage device including these transistors with a simple process as well as realize fine patterning of the low-breakdown-voltage MOS transistor.

What is claimed is:

1. A method of manufacturing a semiconductor device having a stacked gate type nonvolatile memory cell and a p-channel type first transistor, comprising:
forming a gate insulating film of the first transistor over a semiconductor substrate;
forming a tunnel insulating film of the stacked gate type nonvolatile memory cell over the semiconductor substrate;
forming a first conductive layer containing an n-type impurity over the tunnel insulating film and the gate insulating film;
implanting p-type impurity to a region of the first conductive layer for forming the first transistor to turn the region of the first conductive layer into a p-type region;
forming an insulating layer over the first conductive layer;
forming a second conductive layer over the insulating layer;
patterning the second conductive layer, the insulating layer, and the first conductive layer to form a stacked gate electrode of the stacked gate type nonvolatile memory cell and a first gate electrode of the first transistor;
implanting a first impurity to the semiconductor substrate using the stacked gate electrode as a mask to form a first extension region; and
implanting a second impurity to the semiconductor substrate using the first gate electrode as a mask to form a second extension region.

2. The method of manufacturing the semiconductor device according to claim 1, wherein the n-type impurity is phosphorous and the p-type impurity is boron.

3. The method of manufacturing the semiconductor device according to claim 1, wherein the first conductive layer and the second conductive layer are formed of polycrystalline silicon.

4. The method of manufacturing the semiconductor device according to claim 1, wherein the insulating layer comprises a laminate insulating film in which a first oxide film, a nitride film, and a second oxide film are laminated in this order.

5. The method of manufacturing the semiconductor device according to claim 1, further comprising:
partially removing the insulating film in a region for forming the gate electrode to expose the first conductive layer after the formation of the insulating layer and before the formation of the second conductive layer.

6. The method of manufacturing the semiconductor device according to claim 1, further comprising:
oxidizing side walls of the first gate electrodes after the formation of the second extension region.

7. A method of manufacturing a semiconductor device having a stacked gate type nonvolatile memory cell, a p-channel type first transistor, and a second transistor having a breakdown voltage lower than a breakdown voltage of the first transistor, comprising:
forming a tunnel insulating film of the stacked gate type nonvolatile memory cell over the semiconductor substrate;
forming a first gate insulating film of the first transistor over the semiconductor substrate;
forming a first conductive layer containing an n-type impurity over the tunnel insulating film and the first gate insulating film;
implanting p-type impurity to a region of the first conductive layer for forming the first transistor to turn the region of the first conductive layer into a p-type region;
removing a region of the first conductive layer for forming the second transistor;
forming an insulating layer over the first conductive layer;
forming a second gate insulating film of the second transistor over the semiconductor substrate;
patterning the second conductive layer, the insulating layer, and the first conductive layer to form a stacked gate electrode of the stacked gate type nonvolatile memory cell and a first gate electrode of the first transistor;
patterning the second conductive layer to form a second gate electrode of the second transistor;
implanting a first impurity to the semiconductor substrate using the stacked gate electrode as a mask to form a first extension region;
implanting a second impurity to the semiconductor substrate using the first gate electrode as a mask to form a second extension region; and
implanting a third impurity to the semiconductor substrate using the second gate electrode as a mask to form a third extension region.

8. The method of manufacturing the semiconductor device according to claim 7, wherein the second extension region is thicker than the second conductive layer.

9. The method of manufacturing the semiconductor device according to claim 7, wherein the second extension region is formed in a deeper portion than the third extension region.

10. A semiconductor device, comprising:
a stacked gate type nonvolatile memory cell; and
a p-channel type first transistor,
the stacked gate type nonvolatile memory cell having a stacked gate electrode including n-type floating gate, first insulating film, and control gate, which are stacked in order over a semiconductor substrate, and first source/drain regions formed on both sides of the stacked gate electrode in the semiconductor substrate, and
the first transistor having a first gate electrode including p-type first electrode, second insulating film, and second electrode, which are stacked in order over the semiconductor substrate, and second source/drain regions formed on both sides of the first gate electrode in the semiconductor substrate.

11. The semiconductor device according to claim 10, wherein the first electrode contains an n-type impurity and a p-type impurity, and a concentration of the p-type impurity is higher than a concentration of the n-type impurity.

12. The semiconductor device according to claim 10, wherein the first electrode and the second electrode are made of polycrystalline silicon.

13. The semiconductor device according to claim 10, wherein the first insulating film and the second insulating film comprises a laminate insulating film in which a first oxide film, a nitride film, and a second oxide film are laminated in this order.

14. The semiconductor device according to claim 10, wherein a portion of the first conductive layer in the first gate electrode is electrically connected to a line of the semiconductor substrate.

15. The semiconductor device according to claim 10, wherein the first conductive layer and the second conductive layer of the first gate electrode are electrically connected.

16. The semiconductor device according to claim 10, wherein the first transistor comprises an extension region thicker than the second electrode.

17. A semiconductor device according to claim 10, further comprising:
a second transistor having a breakdown voltage lower than a breakdown voltage of the first transistor, the second transistor having a gate electrode of a single-layer structure; and second source/drain regions formed on both sides of the first gate electrode in the semiconductor substrate.

18. The semiconductor device according to claim 17, wherein the extension region of the second transistor is thicker than a gate electrode of the second transistor.
